(19) United States
(12) Patent Application Publication
(10) Pub. No.: US 2005/0136622 A1
(43) Pub. Date: Jun. 23, 2005

(54) Methods and apparatus for laser dicing

(76) Inventors: Rose A. Mulligan, Chandler, AZ (US); Sujit Sharan, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/742,186

(22) Filed: Dec. 18, 2003

(51) Int. Cl. B23K 26/14; H01L 21/301; H01L 21/46

(52) U.S. Cl. 438/460; 438/463; 219/121.67

(57) ABSTRACT

An apparatus and method of dicing a microelectronic device wafer by laser ablating at least an interconnect layer portion of the microelectronic device wafer in the presence of an anion plasma, wherein the anion plasma reacts with debris from the laser ablation to form a reaction gas.

### BACKGROUND OF THE INVENTION

1. Field of the Invention

The present invention relates to the dicing of microelectronic device wafers into individual microelectronic dice. In particular, the present invention relates to using a laser dicing in the presence of an anion plasma.

2. State of the Art

In the production of microelectronic devices, integrated circuitry is formed in and on microelectronic device wafers, which is usually comprised primarily of silicon, although other materials such as gallium arsenide and indium phosphide may be used. As shown in FIG. 6, a single microelectronic device wafer 200 may contain a plurality of substantially identical integrated circuits 202, which are usually substantially rectangular and arranged in rows and columns. In general, two sets of mutually parallel dicing streets 204 extend perpendicular to each other over substantially the entire surface of the microelectronic device wafer 200 between each discrete integrated circuit 202.

After the integrated circuits 202 on the microelectronic device wafer 200 have been subjected to preliminary testing for functionality (wafer sort), the microelectronic device wafer 200 is diced (cut apart), so that each area of functioning integrated circuitry 202 becomes a microelectronic die that can be used to form a packaged microelectronic device. One exemplary microelectronic wafer dicing process uses a circular diamond-impregnated dicing saw, which travels down two mutually perpendicular sets of dicing streets 204 lying between each of the rows and columns. Of course, the dicing streets 204 are sized to allow passage of a wafer saw blade between adjacent integrated circuits 202 without causing damage to the circuitry.

As shown in FIGS. 7 and 8, the microelectronic device wafer 200 may have guard rings 206 which substantially surround the integrated circuit 202. The guard rings 206 extend though an interconnect layer 208 (see FIG. 8). The interconnect layer 208 comprises layers 212 consisting of metal traces layer separated by dielectric material layers on a substrate wafer 214. The interconnect layer 208 provides routes for electrical communication between integrated circuit components within the integrated circuits, as well as to external interconnects 220 used in flip chip attachment to external devices (not shown), as will be understood by those skilled in the art. The guard ring 206 is generally formed layer by layer as the interconnect layer 208 is formed. The guard ring 206 assists in preventing external contamination encroaching into the integrated circuitry 202 between the interconnect layer 208.

Prior to dicing, the microelectronic device wafer 200 is mounted onto a sticky, flexible tape 216 (shown in FIG. 8) that is attached to a ridge frame (not shown). The tape 216 continues to hold the microelectronic die after the dicing operation and during transport to the next assembly step. As shown in FIG. 9 and 10, a saw cuts a channel 218 in the dicing street 204 through the interconnect layer 208 and the substrate wafer 214. During cutting, the saw generally cuts into the tape 216 to up to about one-third of its thickness.

However, in the dicing of microelectronic device wafers 200, the use of industry standard dicing saws results in a rough edge along the interconnect layer 208 and results in stresses being imposed on the interconnect layer 208. This effect is most prevalent when the interconnect layer 208 has ductile copper traces or interconnects. This rough edge and the stresses imposed is a source of crack propagation into and/or delamination of the interconnect layer 208, through the guard ring 206, and into the integrated circuitry 202 causing fatal defects.

To eliminate rough edges in the interconnect layer 208, a laser, such as a Nd:YAG Laser (amplifying medium of neodymium-doped yttrium aluminium garnate (YAG)) at 355 nm, may be used to dice the microelectronic device wafer 200 or at least ablate a trench in the interconnect layer 208 (as lasers may cut/ablate slowly through the entire thickness of the microelectronic device wafer) followed by dicing completely through the remainder of the microelectronic device wafer 200 with a standard wafer saw. However, laser ablation of silicon or silicon containing materials (such as silicon dioxide, silicon nitride, or the like, used as dielectric layers in the interconnect layer) results in elemental silicon being released (broken bonds with other chemical elements), which immediately oxidizes and deposits as debris in molten form onto the microelectronic device wafer 200. This debris can cause issues with the attachment of the final product, as it prevents the wetting of the external interconnects 220 between with the external device (not shown).

To prevent such contamination, a chemical resist or other sacrificial layer 222 is deposited over the microelectronic device wafer 200, as shown in FIG. 11. Thus, as debris 224 is generated during laser ablation (i.e., laser beam 226 (illustrated as arrows) cutting into the microelectronic device wafer 200), it is deposited on the sacrificial layer 222. After dicing, the sacrificial layer 222 is removed, leaving substantially debris-free, end product microelectronic dice 230, as shown in FIG. 12. Although the use of the sacrificial layer 222 is effective, it requires additional processing steps of applying the sacrificial layer 222, patterning (if necessary), and removal of the sacrificial layer 222. These additional steps increase the cost of the end product microelectronic dice 230.

Therefore, it would be advantageous to develop apparatus and techniques to effectively dice microelectronic device wafers with a laser while reducing or substantially eliminating the deposition of debris on the end product microelectronic die.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings to which:

FIG. 1 is a side cross-sectional view of a microelectronic device wafer, according to the present invention;

FIG. 2 is a side cross-sectional view of laser ablating an interconnect layer of the microelectronic device wafer in the presence of an anion plasma, according to the present invention;

FIG. 3 is a side cross-sectional view of a trench formed in the interconnect layer of the microelectronic device wafer, according to the present invention;

FIG. 4 is a side cross-sectional view of wafer sawing the substrate wafer of the microelectronic device wafer, according to the present invention;

FIG. 5 is a side cross-sectional view of a schematic of an apparatus according to the present invention;

FIG. 6 is a top plan view of a conventional microelectronic device wafer having a plurality of unsingulated microelectronic devices, as known in the art;

FIG. 7 is a top plan close-up view of insert 7 of FIG. 8 showing the dicing street areas, as known in the art;

FIG. 8 is a side cross-sectional view of the dicing street areas of a microelectronic device wafer along line 8-8 of FIG. 7, as known in the art;

FIG. 9 is a top plan close-up view of the microelectronic device wafer after dicing, as known in the art;

FIG. 10 is a side cross-sectional view of the dicing street areas of a microelectronic device wafer along line 10-10 of FIG. 9, as known in the art;

FIG. 11 is a side cross-sectional view of the laser ablating the microelectronic device wafer having a sacrificial layer disposed thereon, as known in the art; and

FIG. 12 is a side cross-sectional view of the microelectronic device wafer of FIG. 11 after dicing and removal for the sacrificial layer, as known in the art.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention includes apparatus and methods of dicing a microelectronic device wafer by laser ablating at least an interconnect layer portion of the microelectronic device wafer in the presence of an anion plasma, wherein the anion plasma reacts with debris from the laser ablation to form a reaction gas.

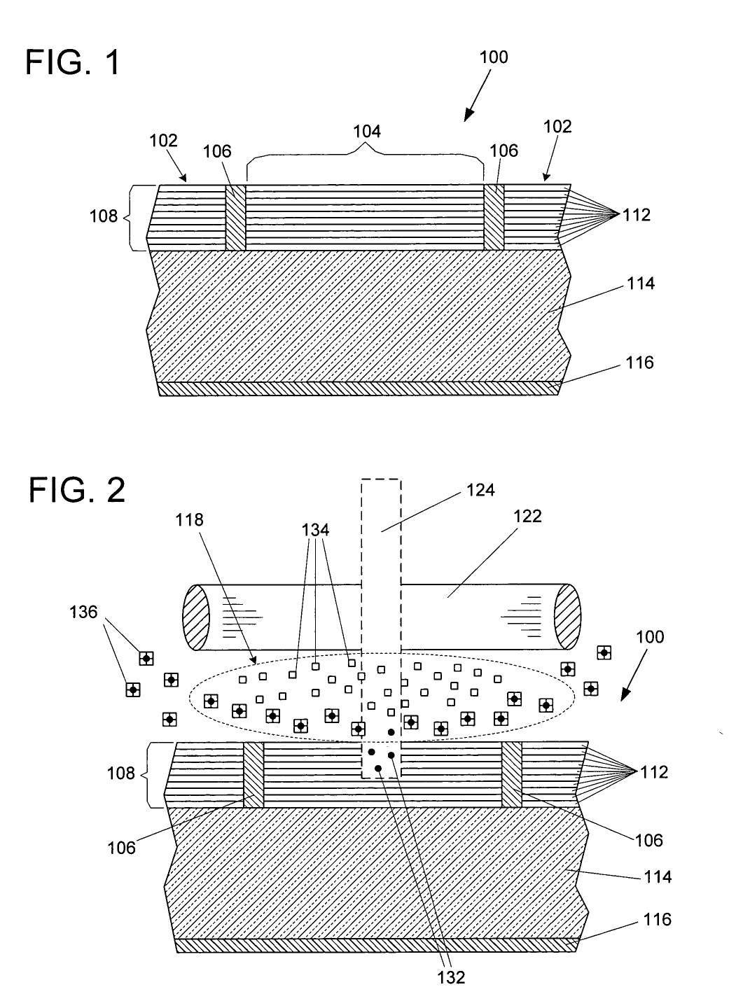

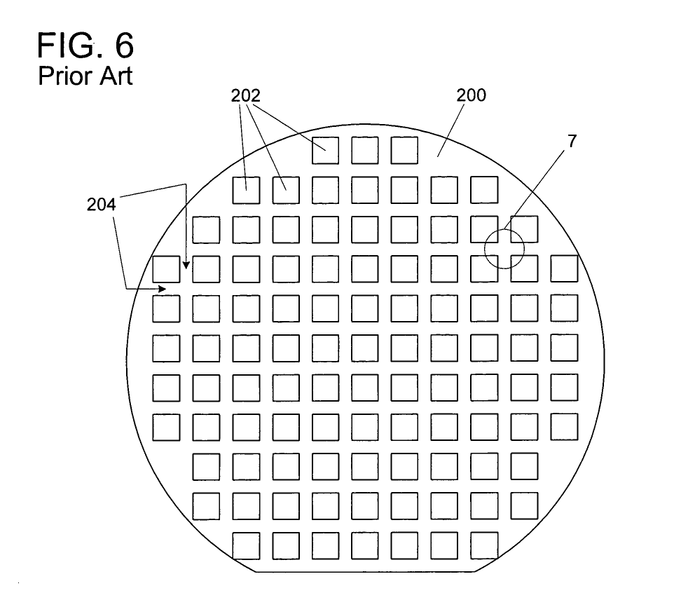

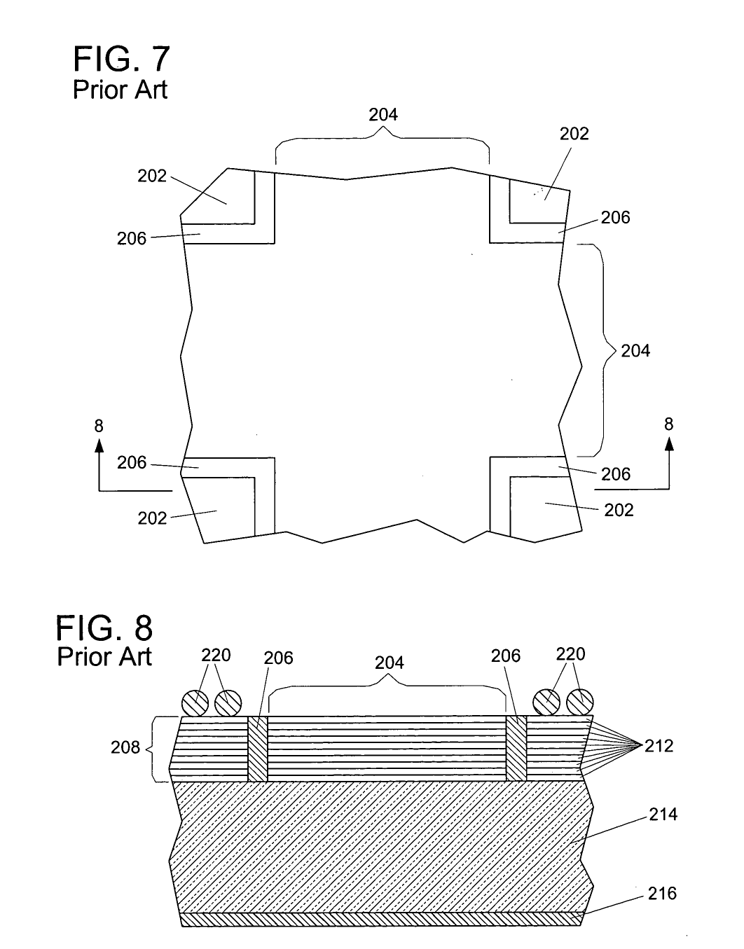

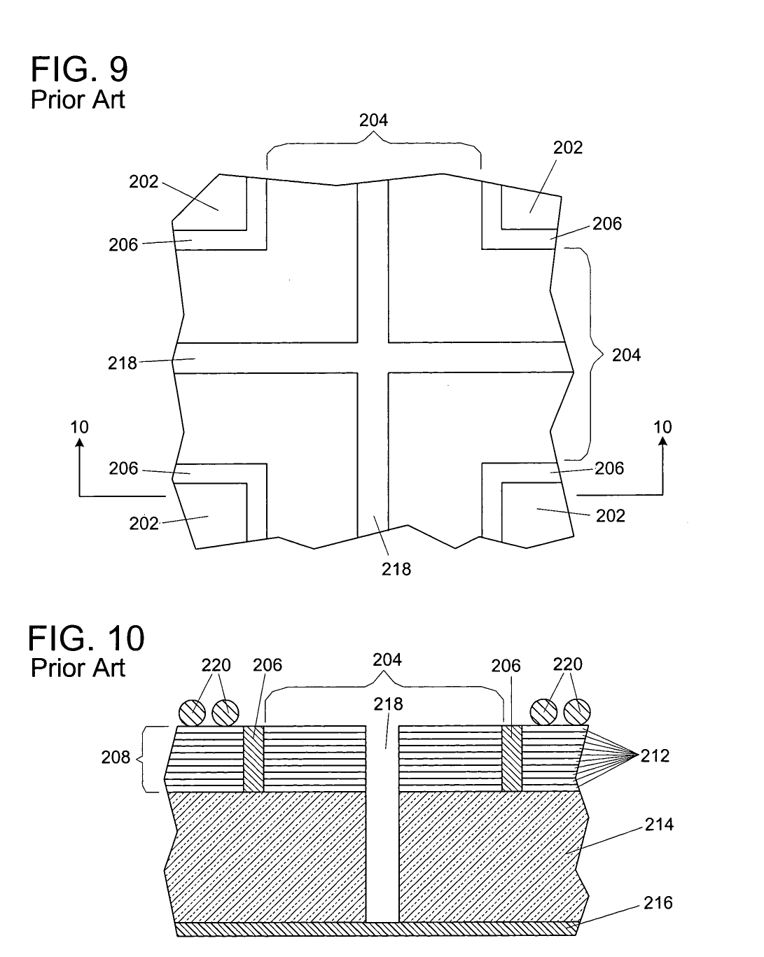

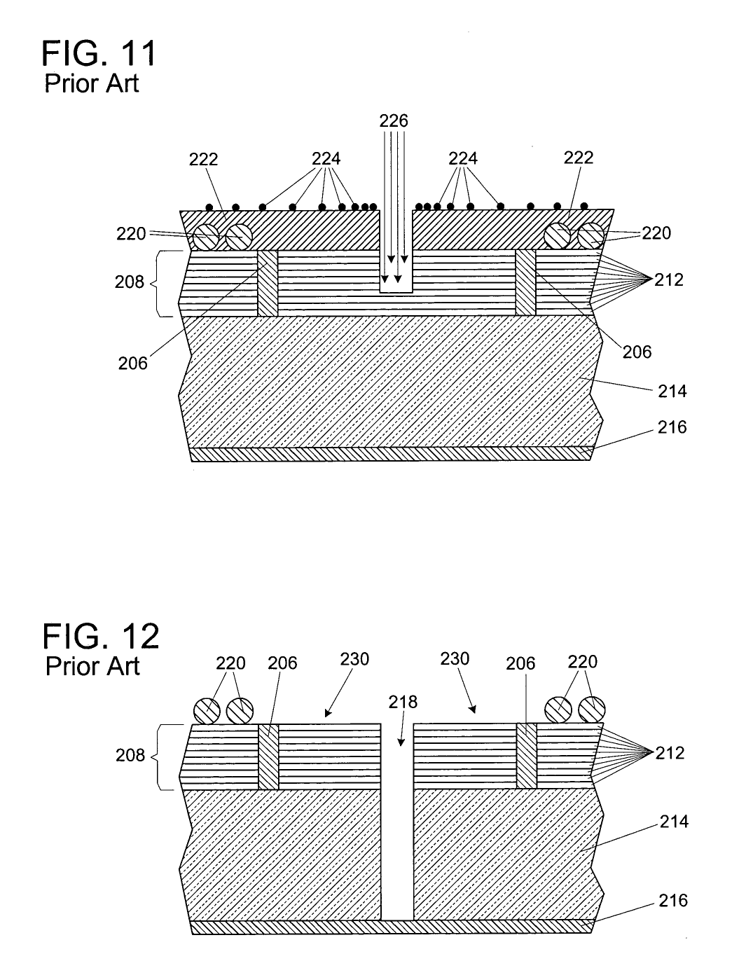

FIG. 1 illustrates a microelectronic device wafer 100 similar to the microelectronic device wafer 200 of FIGS. 6 and 7 comprising a substrate wafer 114, including, but not limited to, silicon, gallium arsenide and indium phosphide, mounted onto a sticky, flexible tape 116 and an interconnect layer 108 disposed on the substrate wafer 114. It is, of course, understood that the use of the term “wafer” does not only include an entire wafer, but also includes portions thereof.

The interconnect layer 108 is generally alternating layers 112 of dielectric material, including but not limited to silicon dioxide, silicon nitride, fluorinated silicon dioxide, carbon-doped silicon dioxide, silicon carbide, various polymeric dielectric materials (such as SiLK available for Dow Chemical, Midland, Mich.), and the like, and patterned electrically conductive material, including copper, aluminum, silver, titanium, alloys thereof, and the like. The methods and processes for fabricating the interconnect layer 108 as well as the minor constituent materials in the various layers thereof will be evident to those skilled in the art.

As previously discussed, a plurality of dicing streets 104 separates individual integrated circuitry 102. Generally, the dicing streets 104 run perpendicularly to separate the integrated circuitry 102 into rows and columns. At least one guard ring 106 may isolate integrated circuitry 102 from dicing streets 104, as discussed previously in relation to FIGS. 6 and 7. Within the dicing streets 104, there are typically test structures that are composed of the same materials as the other parts of the interconnect layer 108. Between these test structures in the dicing street 104 and the guard ring 106 may be a region or regions composed entirely of dielectric material with no conductive material.

One embodiment of the present invention includes using a laser, such as a Nd:YAG Laser (amplifying medium of neodymium-doped yttrium aluminium garnate (YAG)) (for example, a Model 2700 Micromachining System made by Electro Scientific Industries, Inc. of Portland, Oreg., USA), to ablate away at least a portion of the microelectronic device wafer 100 (for example ablating through the interconnect layer 108). However, this laser ablation is performed in the presence of an anion plasma. The anion plasma generation is, well known in the art, wherein gases such as fluorine (F₂), chlorine (Cl₂), and/or the like is charged into an anion plasma (F⁻, Cl⁻, and/or the like, respectively). The specific operating parameters of a plasma generating system will vary depending on the gas used, as will be understood by those skilled in the art.

In one embodiment, as shown in FIG. 2, an anion plasma 118 (illustrated as a dashed line field) is generated from fluorine gas proximate a charged annular plasma ring 122 located near the interconnect layer 108 (e.g., between about 2 and 3 mm from the interconnect layer 108) containing a silicon material. A laser beam 124 (illustrated as a dashed area) is fired through the annular plasma ring 122 and anion plasma 118 to ablate a desired portion of the interconnect layer 108 within the dicing street 104 (see FIG. 1). As silicon debris 132 (e.g., Si⁺⁴) is generated by the laser ablation, it reacts with ions 134 (e.g., F⁻) in the anion plasma 118 to form a reaction gas 136 (e.g., SiF₄), before it can oxidize and deposit on the microelectronic device wafer 100. In chemical terms, the following reaction occurs:
Si⁺⁴+4F⁻→SiF₄
The resulting reaction gas 136 is simply exhausted from the system. The reaction gas 136 can, of course, recovered and reused in other microelectronic die processing steps. Naturally, this process is not limited to microelectronic device fabrication and can be applied to laser ablating any silicon containing material.

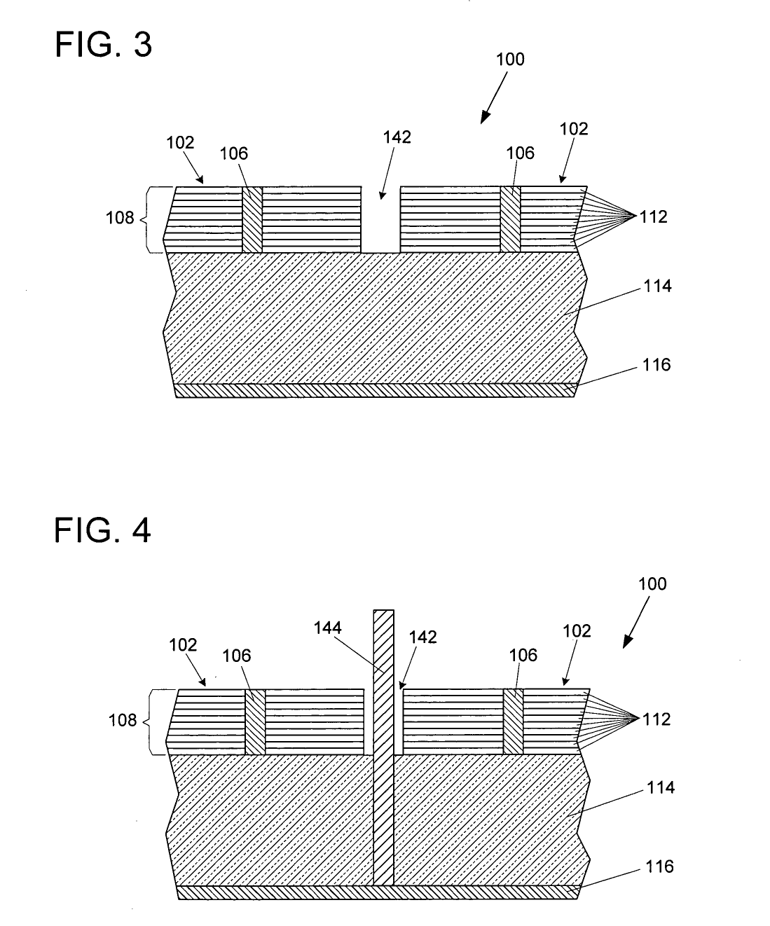

Since the laser beam 124 cuts/ablates a smooth-sided trench 142, it will not propagate cracks in or cause delamination of the layers comprising the interconnect layer 108. Although the laser can cut completely through the microelectronic device wafer 100, it is a slow process. In one embodiment, the laser ablation is discontinued after forming the trench 142 through the interconnect layer 108, as shown in FIG. 3 and a wafer saw 144 may be used to cut through the substrate wafer 114, as shown in FIG. 4. Thus, the wafer saw 144 will cut the microelectronic wafer 100 only within the substrate wafer 114 where crack formation is not a problem. Of course, the width of the wafer saw 144 must be smaller than the width of the trench 142 to prevent damaging the trench side walls.

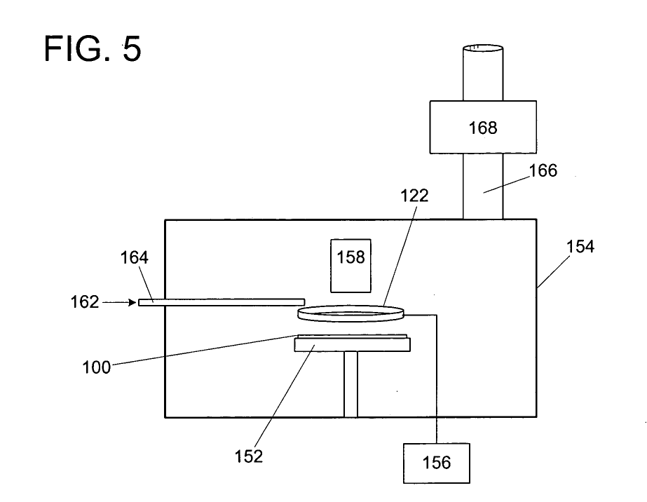

FIG. 5 illustrates a schematic of an apparatus according to the present invention. The microelectronic device wafer 100 may be placed on a pedestal 152 in a containment chamber 154. The plasma ring 122 of a plasma system 156 is positioned proximate the microelectronic device wafer 100. A laser system 158 positioned opposing said pedestal 152 to fire a laser beam 124 (see FIG. 2) through the plasma ring 122 to strike the microelectronic device wafer 100. A feed gas (shown as arrow 162) used for the plasma generation may be delivered through a gas feed line 164 extending into the containment chamber 154 and terminating in a position between the plasma ring 122 and the laser system 158, preferably about 20 mm from the plasma ring 122 to allow the feed gas 162 to be charged to the plasma, but preferably limited to area of ablation of the microelectronic device wafer 100. The containment chamber 154 further includes an exhaust port 166, which removes the reaction gas 136 (see FIG. 2), other debris, excess plasma 118 (see FIG. 2), and/or unreacted feed gas 162. A scrubber 168 may be placed on the exhaust port 166 to remove harmful gases prior to venting to the atmosphere and/or to strip of various gases for reuse in other processing steps, as will be understood to those skilled in the art. Again, it is understood that this apparatus can be used to ablate any silicon-containing material.

Having thus described in detail embodiments of the present invention, it is understood that the invention defined by the appended claims is not to be limited by particular details set forth in the above description, as many apparent variations thereof are possible without departing from the spirit or scope thereof.

1. A method of dicing a microelectronic device wafer, comprising:
providing a microelectronic device wafer comprising a substrate wafer having an interconnect layer disposed thereon, said microelectronic device including at least two integrated circuits formed therein separated by at least one dicing street;
generating an anion plasma proximate said interconnection layer; and
laser ablating at least one trench through said interconnect layer within said at least one dicing street by firing a laser beam through said anion plasma.

2. The method of claim 1, further comprising discontinuing said laser ablating after ablating through said interconnect layer and cutting through said substrate wafer within said at least one trench with a wafer saw.

3. The method of claim 1, wherein generating said anion plasma includes generating said anion plasma with fluorine gas.

4. The method of claim 1, wherein generating said anion plasma includes generating said anion plasma with chlorine gas.

5. The method of claim 1, wherein generating said anion plasma comprising generating an anion plasma with a plasma ring placed proximate said interconnect layer.

6. The method of claim 5, wherein laser ablating comprises firing said laser beam through said plasma ring.

7. A method of laser ablation, comprising:
providing a silicon-containing material;
generating an anion plasma proximate said silicon-containing material; and
laser ablating said silicon-containing material by firing a laser beam through said anion plasma.

8. The method of claim 7, wherein generating said anion plasma includes generating said anion plasma with a fluorine gas.

9. The method of claim 7, wherein generating said anion plasma includes generating said anion plasma with a chlorine gas.

10. The method of claim 7, wherein generating as anion plasma comprising generating an anion plasma with a plasma ring placed proximate said silicon-containing material.

11. The method of claim 10, wherein laser ablating comprises firing said laser beam through said plasma ring.

12. An apparatus for laser ablation, comprising:
a plasma ring of a plasma system; and
a laser system positioned to fire a laser beam through said plasma ring.

13. The apparatus of claim 12, further comprising a containment chamber wherein said plasma ring and said laser system reside.

14. The apparatus of claim 13, further comprising an exhaust port attached to said containment chamber.

15. The apparatus of claim 14, further comprising a scrubber placed on said exhaust port.

16. The apparatus of claim 13, further comprising a feed gas line extending into said containment chamber and terminating proximate said plasma ring.

17. The apparatus of claim 16, wherein said feed gas line terminates between said laser system and said plasma ring.

18. The apparatus of claim 12, further comprising a pedestal positioned opposing said laser system with said plasma ring therebetween.

19. The apparatus of claim 18, further comprising a silicon-containing material positioned on said pedestal.

20. The apparatus of claim 18, further comprising a microelectronic device wafer positioned on said pedestal.
